(19) United States
(12) Patent Application Publication
(10) Pub. No.: US 2023/0282693 A1
(43) Pub. Date: Sep. 7, 2023

(54) TRENCH CHANNEL SEMICONDUCTOR DEVICES AND RELATED METHODS

(71) Applicant: SEMICONDUCTOR COMPONENTS INDUSTRIES, LLC, Phoenix, AZ (US)

(72) Inventors: Kwangwon LEE, Siheung-si (KR); Youngho SEO, Bucheon-si (KR); Hrishikesh DAS, Scarborough, ME (US); Martin DOMEIJ, Stockholm (SE); Kyeongseok PARK, Bucheon (KR)

(73) Assignee: SEMICONDUCTOR COMPONENTS INDUSTRIES, LLC, Phoenix, AZ (US)

(21) Appl. No.: 17/653,669

(22) Filed: Mar. 7, 2022

(51) Int. Cl. H01L 29/06; H01L 29/10; H01L 29/16; H01L 29/167; H01L 29/78; H01L 21/02; H01L 21/04; H01L 21/76; H01L 21/761; H01L 29/66

(52) U.S. Cl. CPC H01L 29/0634; H01L 29/1095; H01L 29/1608; H01L 29/167; H01L 29/7813; H01L 21/02529; H01L 21/0465; H01L 21/7602; H01L 21/761; H01L 29/66068

(57) ABSTRACT

Implementations of a semiconductor device may include a trench including a gate and a gate oxide formed therein, the trench extending into a doped pillar of a first conductivity type formed in a substrate material. The device may include a trench channel adjacent to the trench and two doped pillars of a second conductivity type extending on each side of the first conductivity type doped pillar where a ratio of a depth of each of the two second conductivity type doped pillars to a depth of the trench into the substrate material may be at least 1.6 to 1.

### BACKGROUND

### 1. Technical Field

Aspects of this document relate generally to semiconductor device, such as transistor devices. More specific implementations involve power semiconductor devices.

### 2. Background

Semiconductor devices are formed in the material of a semiconductor substrate and are designed to control the flow of electricity in the form of current and/or change through the semiconductor substrate. A wide variety of semiconductor devices have been devised to control the flow of electricity in various ways and using various control structures.

### SUMMARY

Implementations of a semiconductor device may include a trench including a gate and a gate oxide formed therein, the trench extending into a doped pillar of a first conductivity type formed in a substrate material. The device may include a trench channel adjacent to the trench and two doped pillars of a second conductivity type extending on each side of the first conductivity type doped pillar where a ratio of a depth of each of the two second conductivity type doped pillars to a depth of the trench into the substrate material may be at least 1.6 to 1.

Implementations of semiconductor devices may include one, all, or any of the following:

The first conductivity type doped pillar may be n-type doped with nitrogen and the second conductivity type doped pillars may be p-type doped with aluminum.

The depth of each of the two p-type doped pillars may extend between 0.5 to over 2 microns into the substrate material beyond the depth of the trench into the substrate material.

The substrate material may be silicon carbide.

The device may include p+ and n+ doped regions on either side of the trench adjacent to the trench channel.

The device may be included in two or more epitaxial layers of silicon carbide.

Implementations of a semiconductor device may include a trench including a gate and a gate oxide formed therein, the trench extending into an n-type doped pillar formed in a substrate material. The device may include a trench channel adjacent to the trench and two p-type doped pillars extending on each side of the n-type doped pillar into the substrate material where the two p-type doped pillars each include a first region adjacent to the trench channel and a second region where the second region may be wider than the first region.

Implementations of a semiconductor device may include one, all, or any of the following:

The n-type doped pillar may be doped with nitrogen and the two p-type doped pillars may be doped with aluminum.

The substrate material may be silicon carbide.

The device may include p+ and n+ doped regions on either side of the trench adjacent to the trench channel.

The device may be included in two epitaxial layers of silicon carbide.

Implementations of a semiconductor device may include a trench including a gate and a gate oxide formed therein, the trench extending into an n-type doped pillar formed in a substrate material, a trench channel adjacent to the trench, and two p-type doped pillars extending on each side of the n-type doped pillar. The n-type doped pillar may have a higher concentration of n-type dopant than a concentration of n-type dopant in the substrate material.

Implementations of a semiconductor device may include one, all, or any of the following:

The n-type doped pillar may be doped with nitrogen and the two p-type doped pillars may be doped with aluminum.

The substrate material may be silicon carbide.

The device may include where an n-type dopant concentration of the n-type doped pillar may be configured to adjust a capacitance curve of the device.

The device may include p+ and n+ doped regions on either side of the trench adjacent to the trench channel.

The device may be included in two epitaxial layers of silicon carbide.

Implementations of a semiconductor device may include a trench including a gate and a gate oxide formed therein, the trench extending into an n-type doped pillar formed in a substrate material. The device may include a trench channel adjacent to the trench and two p-type doped pillars extending on each side of the n-type doped pillar. The n-type doped pillar may have a varying concentration of n-type dopant from a first portion adjacent to the gate oxide to a second portion adjacent to the substrate material.

Implementations of semiconductor devices may include one, all, or any of the following:

The n-type doped pillar may be doped with nitrogen and the two p-type doped pillars may be doped with aluminum.

The substrate material may be silicon carbide.

The device may include where an n-type dopant concentration gradient increases from the first portion to the second portion.

The device may include where an n-type dopant concentration of the n-type doped decreases from the first portion to the second portion.

The device may include p+ and n+ doped regions on either side of the trench adjacent to the trench channel.

The device may be included in two epitaxial layers of silicon carbide.

Implementations of a method of forming a semiconductor device may include implanting a silicon carbide substrate with a p-type dopant to form a plurality of p-type doped regions in the silicon carbide substrate; implanting the silicon carbide with an n-type dopant to form a plurality of n-type doped regions in the silicon carbide substrate; growing an epitaxial silicon carbide layer on the silicon carbide substrate after implanting the silicon carbide substrate with the n-type dopant; and, after growing the epitaxial silicon carbide layer, implanting with a p-type dopant to form a plurality of p-type doped pillars in the silicon carbide substrate. The method may include implanting with an n-type dopant to form a plurality of n-type doped pillars in the silicon carbide substrate; forming a plurality of trenches into the plurality of n-type doped pillars; depositing a gate oxide into the plurality of trenches; depositing a polysilicon oxide material into the plurality of trenches; and forming a plurality of contacts coupled with the polysilicon oxide material and the gate oxide.

Implementations of a method of forming a semiconductor device may include one, all, or any of the following:

Implanting the silicon carbide substrate with the p-type dopant to form the plurality of p-type doped regions in the silicon carbide substrate further may include : first forming a hard mask pattern having a plurality of first openings at a first opening width before implanting with the p-type dopant to form the plurality of p-type doped regions; and after growing the epitaxial silicon carbide layer, first forming a hard mask pattern having a plurality of second openings at a second opening width before implanting with the p-type dopant to form the plurality of p-type doped pillars. The second opening width may be smaller than the first opening width.

Implanting the silicon carbide substrate with the n-type dopant to form the plurality of n-type doped regions in the silicon carbide substrate further may include implanting a first predetermined number of times with the n-type dopant; and wherein implanting with the n-type dopant to form the plurality of n-type doped pillars in the silicon carbide substrate further may include implanting a second predetermined number of times with the n-type dopant where the first predetermined number of times may be more than the second predetermined number of times.

Implanting the silicon carbide substrate with the n-type dopant to form the plurality of n-type doped regions in the silicon carbide substrate further may include implanting a first predetermined number of times with the n-type dopant; and wherein implanting with the n-type dopant to form the plurality of n-type doped pillars in the silicon carbide substrate further may include implanting a second predetermined number of times with the n-type dopant where the first predetermined number of times may be less than the second predetermined number of times.

Implanting the silicon carbide substrate with the n-type dopant to form the plurality of n-type doped regions in the silicon carbide substrate further may include implanting a first predetermined number of times with the n-type dopant; and wherein implanting with the n-type dopant to form the plurality of n-type doped pillars in the silicon carbide substrate further may include implanting a second predetermined number of times with the n-type dopant where the first predetermined number of times may be the same as the second predetermined number of times.

The method may include varying a capacitance curve using an n-type dopant concentration of the n-type doped pillars.

Implementations of a semiconductor device may include a trench including a gate and a gate oxide formed therein, the trench extending into a doped pillar of a first conductivity type formed in a substrate material; a trench channel adjacent to the trench; and two doped pillars of a second conductivity type extending on each side of the first conductivity type doped pillar where a depth of each of the two second conductivity type doped pillars extends between 0.5 to 2 microns into the substrate material beyond a depth of the trench into the substrate material.

Implementations of a semiconductor device may include one, all, or any of the following:

The first conductivity type doped pillar may be n-type doped with nitrogen and the two second conductivity type doped pillars may be p-type doped with aluminum.

The substrate material may be silicon carbide.

The device may include p+ and n+ doped regions on either side of the trench adjacent to the trench channel.

The device may be included in two or more epitaxial layers of silicon carbide.

The foregoing and other aspects, features, and advantages will be apparent to those artisans of ordinary skill in the art from the DESCRIPTION and DRAWINGS, and from the CLAIMS.

### BRIEF DESCRIPTION OF THE DRAWINGS

Implementations will hereinafter be described in conjunction with the appended drawings, where like designations denote like elements, and:

FIG. 1 is a cross sectional view of an implementation of a trench metal oxide semiconductor field effect transistors (MOSFET);

FIG. 2 is a detail view of the trench MOSFET of FIG. 1;

FIG. 3 a cross section view of a simulation of the electrical field of the trench MOSFET of FIG. 1;

FIG. 4 is a one dimensional electric field profile taken along sectional line H-H in FIG. 3;

FIG. 5 is a cross sectional view of another implementation of a trench MO SFET;

FIG. 6 is a detail cross sectional view of the trench MOSFET illustrated in FIG. 5 showing sectional lines A-A and B-B;

FIG. 7 is a one dimensional graph of dopant concentration by depth into the substrate at sectional lines A-A and B-B of FIG. 6;

FIG. 8 is a flow diagram of an implementation of a method of forming a trench MOSFET implementation;

FIG. 9 is a detail cross sectional view of an implementation of a trench MOSFET like that illustrated in FIG. 1;

FIG. 10 is a detail cross sectional view of an implementation of a trench MOSFET implementation like that illustrated in FIG. 5;

FIG. 11 is a detail cross sectional view of a simulation of the electrical field of the trench MOSFET of FIG. 10 showing sectional line C-C;

FIG. 12 is a detail cross sectional view of a simulation of the electrical field of the trench MOSFET of FIG. 11 showing sectional D-D;

FIG. 13 is a graph of absolute electrical field by depth into the substrate for the implementations of trench MOSFETs illustrated in FIGS. 11 and 12 with a detail view showing the voltage of the electric field at the corner of the oxide region;

FIG. 14 is a detail cross sectional view of an implementation of a trench MOSFET showing a p-type doping profile;

FIG. 15 is a detail cross sectional view of another implementation of a trench MOSFET showing another p-type doping profile with a wider second portion;

FIG. 16 is a detail cross sectional view of a simulation of an electrical field of the trench MOSFET of FIG. 14 showing cross sectional line I-I;

FIG. 17 is a detail cross sectional view of a simulation of an electrical field of the trench MOSFET of FIG. 15 showing cross sectional line J-J;

FIG. 18 is a graph of absolute electrical field by depth into the substrate for the implementations of trench MOSFETs illustrated in FIGS. 16 and 17 at the cross sectional lines I-I and J-J;

FIG. 19 is a graph of absolute electrical field by drain voltage for the trench MOSFET implementations of FIGS. 16 and 17;

FIG. 20 is a detail cross sectional view of an implementation of a trench MOSFET with a n-type doped pillar at a first concentration showing sectional line E-E;

FIG. 21 is a detail cross sectional view of an implementation of a trench MOSFET with an n-type doped pillar at a second concentration showing sectional line F-F;

FIG. 22 is a detail cross sectional view of an implementation of a trench MOSFET with a n-type doped pillar at a third concentration showing sectional line G-G;

FIG. 23 is a graph of one dimensional dopant concentration for the trench MOSFET implementations of FIGS. 21-23 along sectional lines E-E, F-F, and G-G;

FIG. 24 is a graph of absolute electrical field versus drain voltage for the three trench MOSFET implementations of FIGS. 21-23;

FIG. 25 is a graph of a detail view of a trench MOSFET implementation with a substantially constant n-type dopant concentration in the n-type doped pillar showing sectional line K-K;

FIG. 26 is a graph of a detail view of a trench MOSFET implementation with an increasing n-type dopant profile into the substrate showing sectional line L-L;

FIG. 27 is a graph of a detail view of a trench MOSFET implementation with an decreasing n-type dopant profile into the substrate showing sectional M-M;

FIG. 28 is a graph of one dimensional n-type dopant concentration by depth into the substrate for the trench MOSFET implementations of FIGS. 26-28 at sectional lines K-K, L-L, and M-M;

FIG. 29 is a three dimensional section drawing of an implementation of a trench MOSFET following gate oxide growth;

FIG. 30 is a three dimensional section drawing of the implementation of the trench MOSFET of FIG. 29 showing just the silicon carbide portions;

FIG. 31 is a detail view of the three dimensional section drawing of FIG. 29;

FIG. 32 is a detail view of the three dimensional section drawing of FIG. 30.

### DESCRIPTION

This disclosure, its aspects and implementations, are not limited to the specific components, assembly procedures or method elements disclosed herein. Many additional components, assembly procedures and/or method elements known in the art consistent with the intended trench channel semiconductor devices will become apparent for use with particular implementations from this disclosure. Accordingly, for example, although particular implementations are disclosed, such implementations and implementing components may comprise any shape, size, style, type, model, version, measurement, concentration, material, quantity, method element, step, and/or the like as is known in the art for such trench channel semiconductor device, and implementing components and methods, consistent with the intended operation and methods.

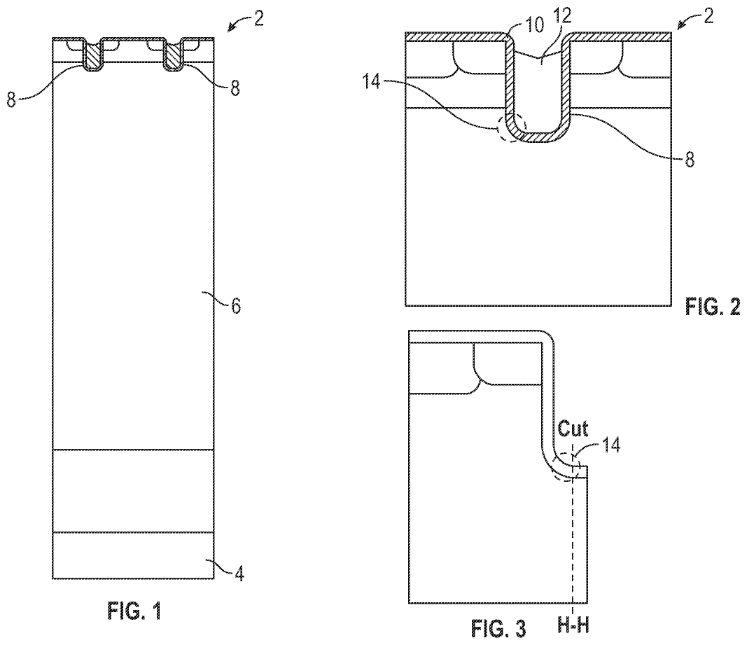

Referring to FIG. 1, a cross sectional view of an implementation of a trench channel semiconductor device 2 is illustrated. As illustrated, the device 2 is formed on a substrate (substrate material) 4, which is, in this case, a silicon carbide substrate. An epitaxial layer 6 of silicon carbide has been grown on the substrate 4. In particular implementations, the epitaxial layer is a single layer and is grown to about 10 microns high/thick on the substrate 4 doped with a dopant of a first conductivity type. In this implementation, the first conductivity type is an n-type dopant at a concentration of 9.5×10¹⁵/cm³. Trenches 8 have been formed in the material of the epitaxial layer 6. Referring to the detail view in FIG. 2 of the device implementations of FIG. 1, a gate oxide 10 has been deposited over the trench and a polysilicon gate material 12 has been deposited into the trench. The device 2 is designed to be a trench metal oxide semiconductor field effect transistors (trench MOSFET) and, in the implementation illustrated, designed as a power semiconductor device capable of handling 1200 V. The advantages of using a trench channel MOSFET design in a power semiconductor device application is that such devices may have lower Rdson and less switching losses due to better channel mobility coupled with smaller cell pitch compared to a planar channel MOSFET design. However, the trench design creates an operating condition that when the device is operated in reverse bias mode using silicon carbide, the corner oxide 14 experiences a very large electric field due to the higher critical electric field value that silicon carbide possesses. Due to the concentration of electric field on the corner oxide, the breakdown voltage of the trench MOSFET may not be sufficient to meet the design requirement of 1200 V without the assistance of other device protections due to breakdown of the corner oxide.

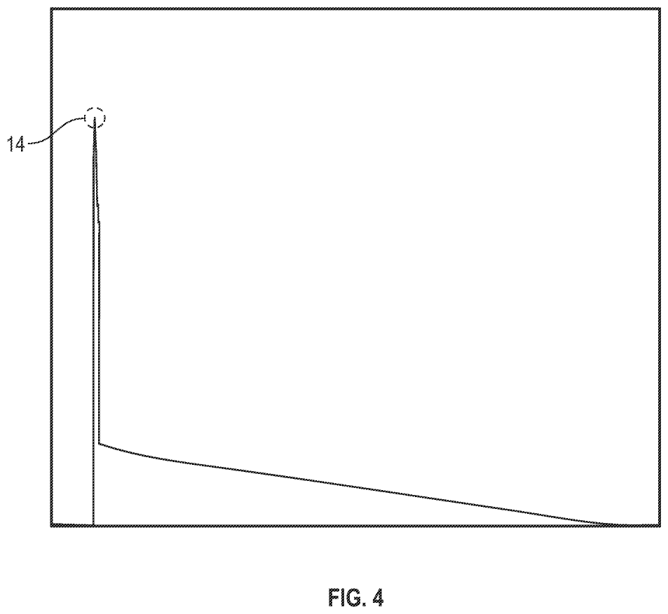

Referring to FIG. 3, a cross sectional view of a simulation of the electric field profile in the structure illustrated in FIG. 2 with sectional line H-H is illustrated showing the region circled with the highest magnitude of the absolute electric field. FIG. 4 illustrates the one dimensional electric field along sectional line H-H by depth into the material of the substrate and illustrates the spike in absolute electric field that corresponds with the upper surface of the corner oxide 14. Because of the intensity of the spike, the breakdown voltage of the device illustrated in FIGS. 1 and 2 is only 754 V, which means that secondary protection will need to be provided to this device during operation at 1200 V to prevent destruction of the device in reverse bias mode.

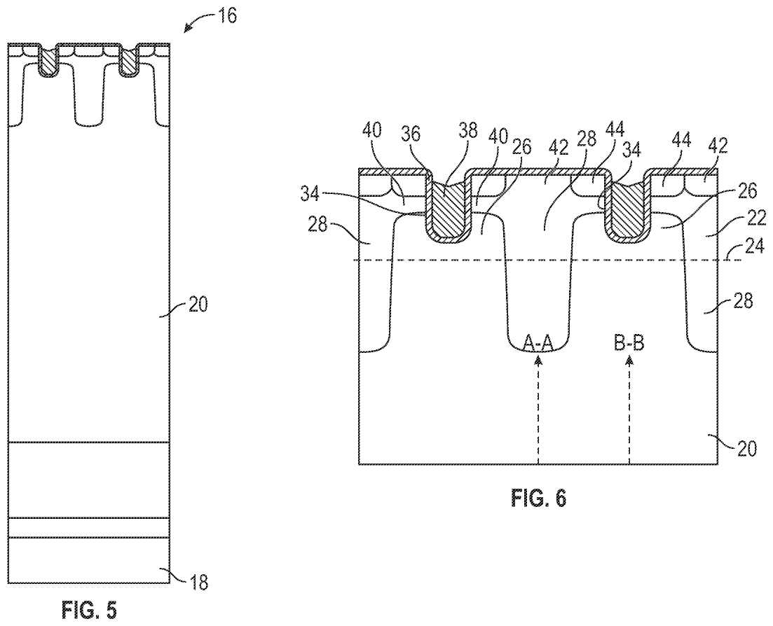

Referring to FIG. 5, another implementation of a trench MOSFET 16 also designed for operation at 1200 V is illustrated. Like the device of FIG. 1, the device 16 is formed on a substrate 18 of silicon carbide upon which an about 10 micron thick epitaxial layer 20 has been grown. Referring to FIG. 6, however, an additional/second epitaxial layer 22 (regrown layer) has been grown on top of the epitaxial layer 20 that is about 1 micron thick, as illustrated by indicator line 24 in FIG. 6. This layer may be thicker or thinner than micron depending upon the electrical characteristics of the device to be formed in various implementations. In some implementations, the layer may be 2, 3, or more microns thick. In various method implementations, multiple regrown layers may be formed one on each other to reach a desired second epitaxial layer thickness (and, as will be described further) a desired pillar depth of a second conductivity type into the material of the substrate).

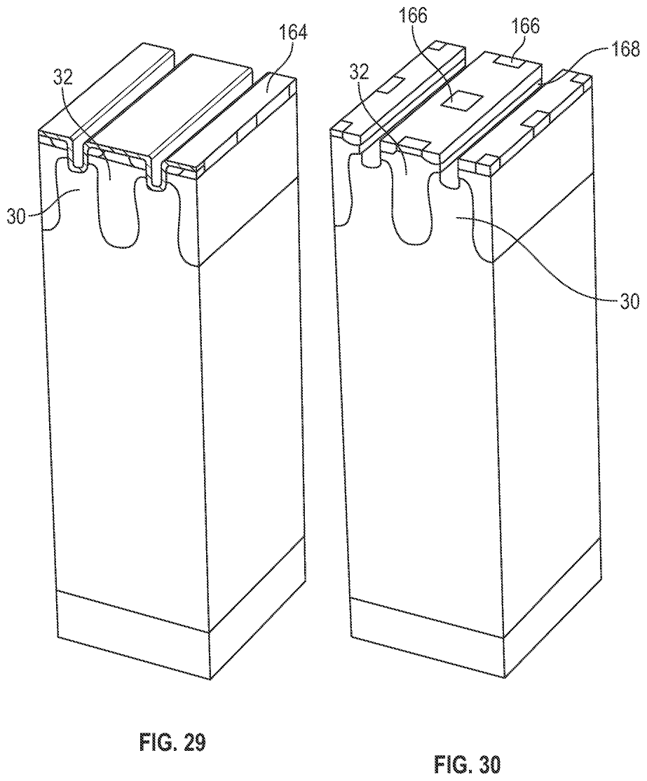

Pillars of a first conductivity type material are illustrated by pillars of a second conductivity type material. In the implementations illustrated in FIG. 5, the first conductivity type is n-type doped material (n-type doped pillars) 26 surrounded on each side by pillars of second conductivity type p-type doped material (p-type doped pillars) 28, both formed using ion implantation during processing as will be subsequently described hereafter. In various implementations, however, the first conductivity type could be n-type doped material and the second conductivity type could be p-type doped material. The term “pillars” as used herein, is used to describe the appearance of the implanted structure in cross section for the purposes of simple explanation. However, in actual fact, the pillar structures appear as alternating n-type and p-type doped projection-shaped or trench-shaped doped regions 30, 32, respectively, in the material of the substrate as illustrated in the three dimensional views of the structure in FIGS. 29-32. However, in this document, for ease of reference to the cross sectional views, the structures are be referred to as “pillars” with the understanding that the three dimensional structures appear projection-shaped (in the n-type case) or trench-shaped (in the p-type case).

Referring to FIG. 6, trenches 34 are formed into the material of the second epitaxial layer 22 into which gate oxide 36 and gate material 38 have been deposited. While in the implementation illustrated in FIG. 6, the trenches 34 extend only into the material of the second epitaxial layer 22, in other implementations, the trenches 34 may extend into the material of the first epitaxial layer 20. The trenches 34 extend into the material of the n-type doped pillars 26 forming a p-type doped trench channel 40 on either side of the trenches 34. Additional p⁺ doped regions 42 and n⁺ doped regions 44 are also included above the trench channel 40 in the implementation illustrate in FIG. 6, though in other implementations, one or both of these regions may not be included.

As used herein, the depth of a pillar of material of a given conductivity type into a material is defined as the point (or line of points) into the material where the last peak of the concentration of dopant material concentration is observed. Note that in this implementation, the difference between the lowest point of the depth of the trenches 34 and the depth of the p-doped pillars 28 into the material of the first and second epitaxial layers can be between about 0.5 microns to about 2 microns or greater., In some implementations, the ratio between the depth of the p-doped pillars to the depth of the trenches may be about 1.6 to 1 to 2:1. In other implementations, the ratio between the depth of the p-doped pillars to the depth of the trenches may be greater than 2:1. In various implementations, there may be no theoretical upper limit to the ratio as the described method of forming one or more regrowth layers essentially allows the formation of as many doped regrowth layers as desired. This may be a distinct advantage of this technique when employed with silicon carbide substrates as the difficulties observed in doping silicon carbide material to a desired depth can be substantially reduced simply by employing multiple doped regrowth layers. In the implementation illustrated in FIGS. 5 and 6, the n-type dopant is nitrogen and the p-type dopant is aluminum. Both the first and second epitaxial layers 1 and 2 are doped with nitrogen to a concentration of about 9×10¹⁵/cm³. While the doping level of both epitaxial layers is the same in the implementation illustrated, in others the doping level may be different in each layer.

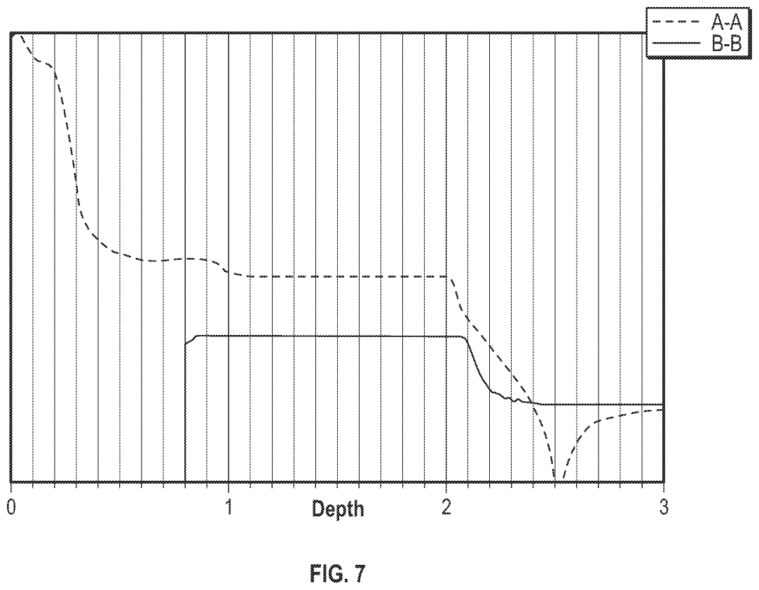

Referring to FIGS. 6 and 7, the one dimensional (into the paper) n-type dopant concentration along sectional line A-A and the p-type dopant concentration along sectional line B-B are illustrated. As illustrated, the concentration of n-type dopant is substantially constant a first distance into the material of the substrate until the last peak of the dopant concentration is observed (at about 2.1 microns for the n-type dopant) and the concentration of the p-type dopant is substantially constant a second distance into the material of the substrate until the last peak of the dopant concentration is observed (at about 1.95 microns). FIG. 7 is a graph illustrating the particular dopant concentration (represented using a logarithmic scale on the Y-axis) versus depth of a particular implementation. Other dopant concentration profiles are possible depending upon the depth desired for each dopant into the material of the substrate. As can be observed from the lines in FIG. 7, the concentration of n-type dopants in the n-type doped pillars and in the p-type doped pillars is substantially constant in the implementation illustrated in FIG. 5.

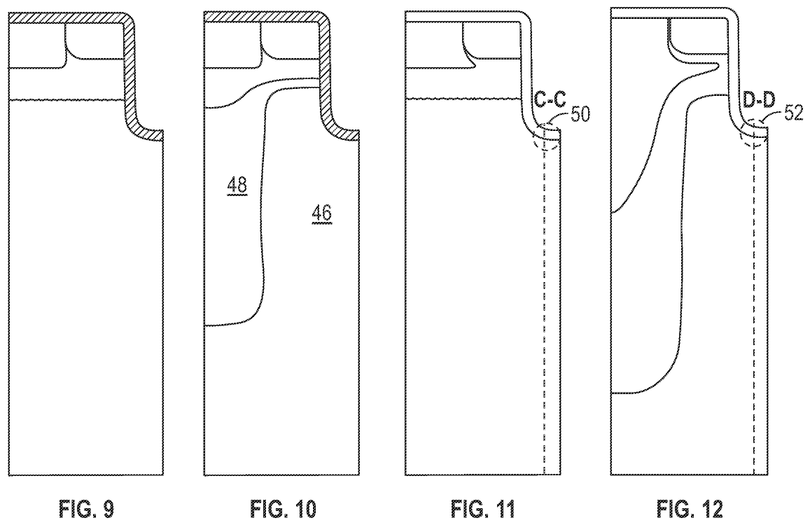

Referring to FIG. 9, a detail cross sectional view of an implementation of a trench MOSFET without pillar structures (like the one illustrated in FIG. 1) is illustrated. FIG. 10 illustrates a detail cross sectional view of another implementation of a trench MOSFET with pillar structures (n-type doped 46 and p-type doped 48). FIG. 11 is a corresponding electric field simulation of the FIG. 10 implementation at breakdown voltage conditions by depth into the material showing sectional line C-C located across the corner oxide region 50 where maximum electric field is experience. FIG. 12 is a corresponding electric field simulation of the FIG. 11 implementation also at breakdown voltage conditions with sectional line D-D located across corner oxide region 52 showing the circled location of the maximum electric field.

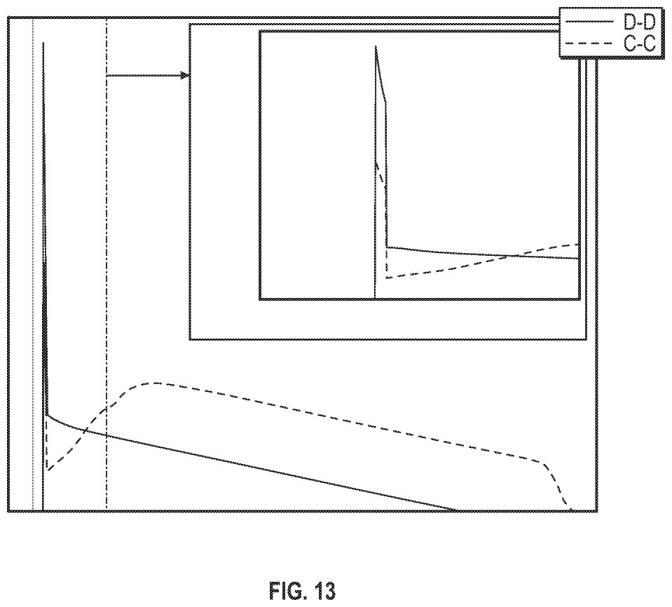

FIG. 13 is a graph of absolute electric field by depth into the substrate along sectional line C-C and sectional line D-D. The breakdown voltage of the FIG. 9 implementation is 754 V in comparison with the breakdown voltage of the FIG. 10 implementation, which is 1566 V, or over two times greater. The detail graph to the upper right shows a magnified version of the larger graph that illustrates how since for the pillar version of the device, the maximum electric field experiences in the corner oxide region 52 is nearly 50% less that the electric field experienced by the corner oxide region 50 of the non-pillar device, this may be a strong factor contributing to the over 50% increase in breakdown voltage of the pillar device.

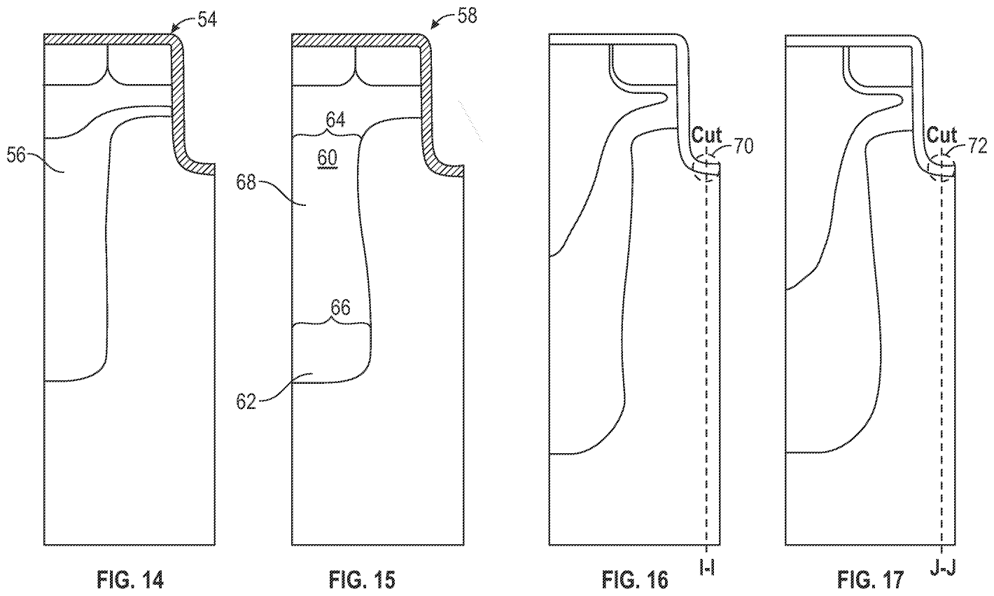

Referring to FIG. 14, a detail cross sectional view of a trench MOSFET device 54 similar to the implementation illustrated in FIG. 10 is illustrated. As with other previously disclosed pillar-containing implementations disclosed in this document, the concentration of p-type dopant in the p-type doped pillar 56 is substantially constant. Referring to FIG. 15, another implementation of a trench MOSFET device 58 is illustrated that has a p-type doped pillar 68 with a first/upper portion 60 and a second/lower portion 62. As illustrated, the upper portion 60 has a first width 64 into the material adjacent to the trench channel of the first two epitaxial layers and the lower portion 62 has a second width 66 where the second width 66 is wider into the material of the first two epitaxial layers than the first width 64 when viewed in cross section. In FIG. 15, the detail view approximately bisects the full width of the pillar, so the dopant profile of the left side of the p-type doped pillar 68 is substantially a mirror image of the dopant profile of the right side. FIG. 16 and FIG. 17 are electrical field simulation graphs at the breakdown condition for the trench MOSFET devices of FIGS. 14 and 15, respectively, showing sectional lines I-I and J-J and the circled regions of highest electric field.

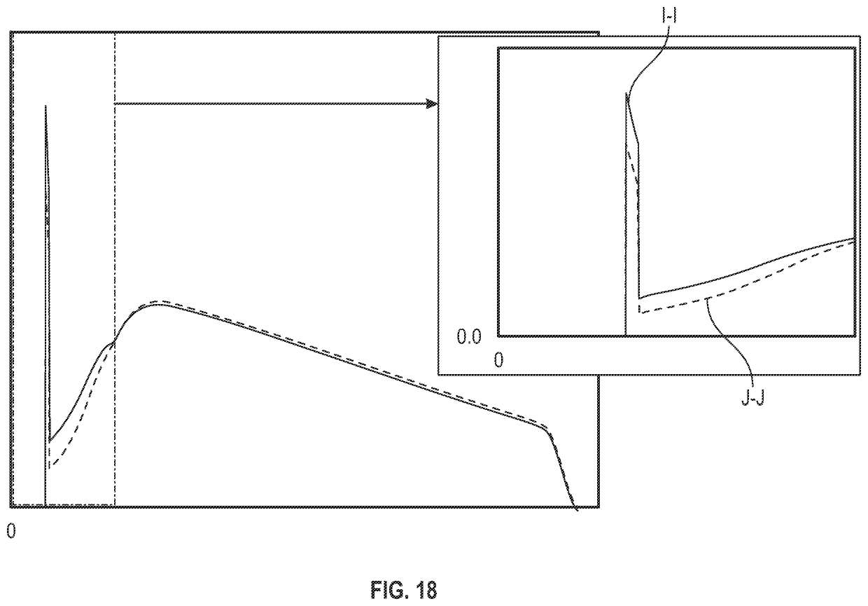

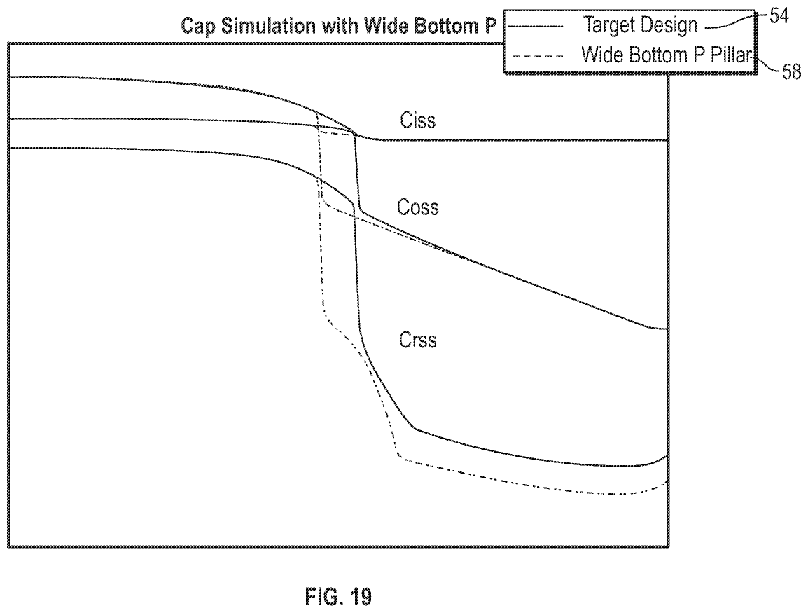

Referring to FIG. 18, a graph of absolute electric field by depth into the substrate is illustrated showing the electric field experienced by the corner oxide regions 70, 72 (see FIGS. 16-17) at breakdown along the sectional lines I-I and J-J. The breakdown voltage for the device 54 of FIG. 14 is 1566 V while the breakdown voltage for the device 58 of FIG. 15 is 1570 V. As the detail view illustrates, the use of the wider bottom p-type pillar design permits the maximum electric field experienced by the corner oxide 72 is about 33% less than the maximum electric field experienced by the corner oxide 70. Because of this, the wider bottom p-type pillar design may be used to reduce the maximum oxide field more during stable operation in reverse blocking mode. Furthermore, the use of the different implantation opening widths during manufacture of the p-type doped pillars (to be discussed later this document) can be used to control the shape of the capacitance curve of the trench MOSFET device, which controls the switching performance of the device. The effect of the wider bottom p-type doped pillar on the capacitance curve plotted on a logarithmic scale forth both absolute electric field and drain voltage (both in V) for the device implementations 54 and 58 are illustrated in the graph of a simulation of absolute electric field versus drain voltage illustrated in FIG. 19 where the effect on input capacitance (Ciss), reverse transfer capacitance (Crss) and output capacitance (Coss) curves are illustrated.

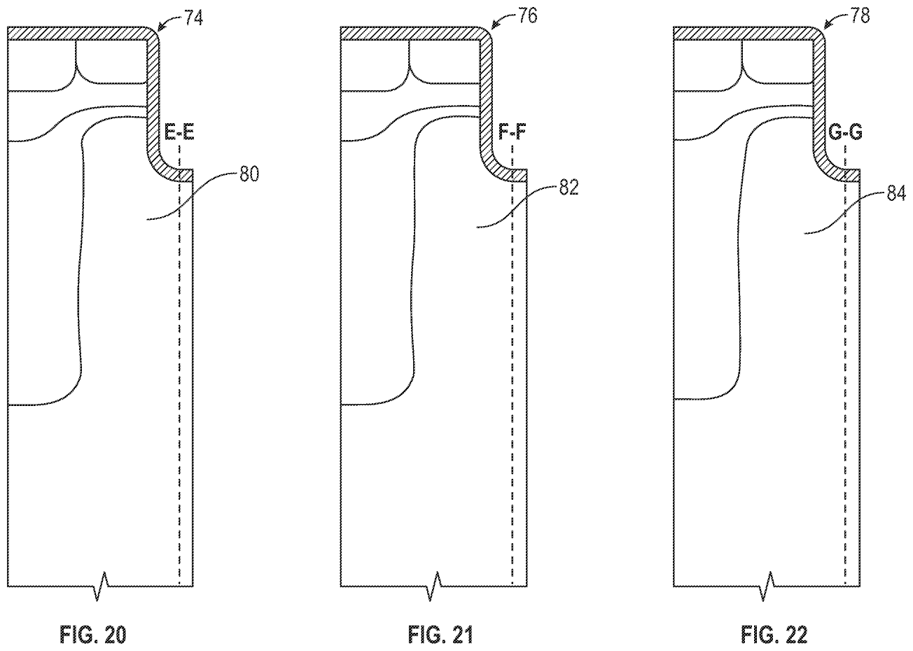

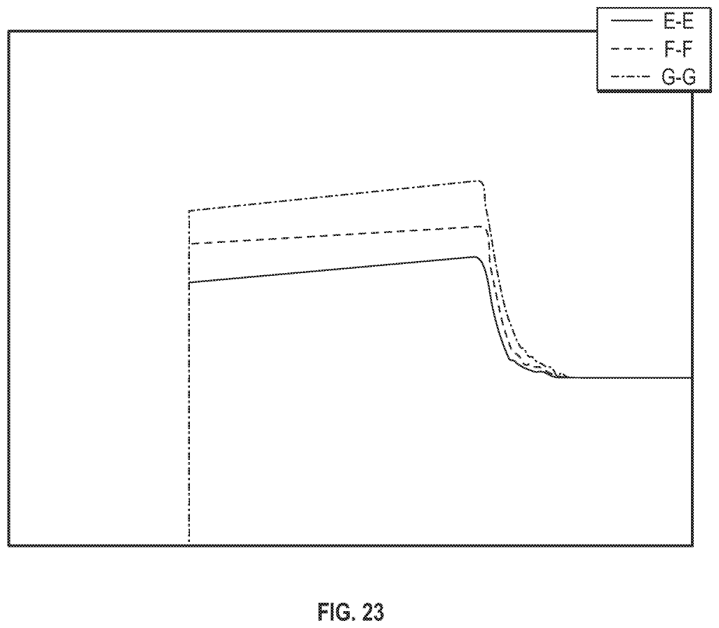

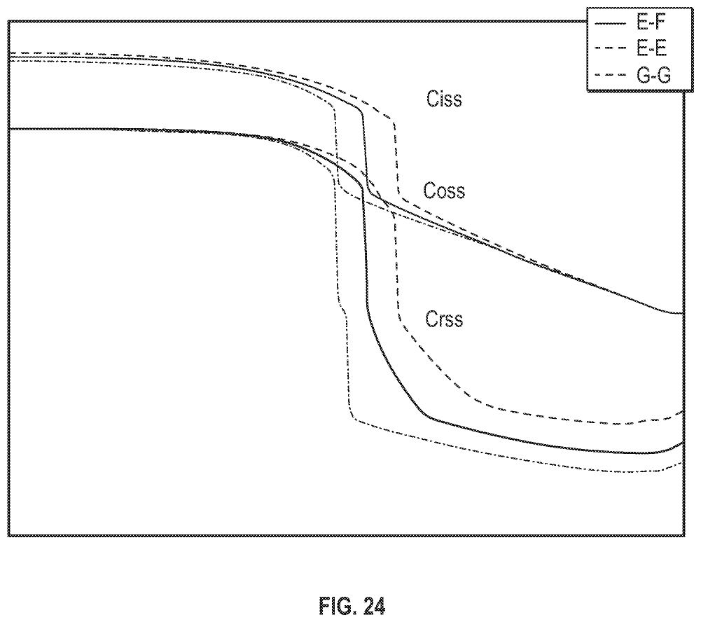

Referring to FIGS. 20-22, three implementations of trench MOSFETs 74, 76, 78 with different, but substantially constant, n-type doping of their respective n-type doped pillars 80, 82, 84 are illustrated. As illustrated, the n-type doping of the n-type doped pillars 80, 82, 84 is a first dopant level, a second dopant level higher than the first, and a third dopant level higher than the first and second., respectively. Various n-dopant concentrations may be used in various implementations such as, by non-limiting example, about 1×10¹⁶ to about 5×10¹⁷/cm³. FIG. 23 is a graph of the logarithm of the 1 dimensional concentration profiles taken into the paper along sectional lines E-E, F-F, and G-G of the n-type dopant in each of the n-type doped pillars 80, 82, 84 showing that the dopant concentration is substantially constant across the depth of the pillar into the material of the first and second epitaxial layers. In various implementations, the changing of the n-type dopant concentration can be used to tune drain-source ON resistance (Rdson) and/or assist with decreasing the maximum oxide electric field experienced by the corner oxide regions. FIG. 24 illustrates how changing the n-type dopant concentration in the n-type doped pillars 80, 82, 84 affects the input capacitance (Ciss), reverse transfer capacitance (Crss) and output capacitance (Coss) curves for the devices of FIGS. 20-22 in a simulation where the logarithm of absolute electric field is plotted versus the logarithm of drain voltage.

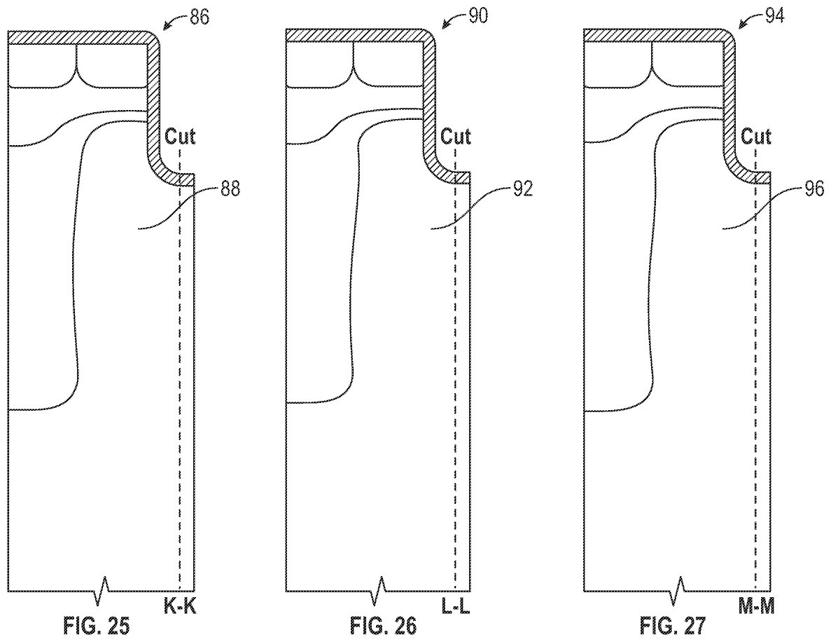

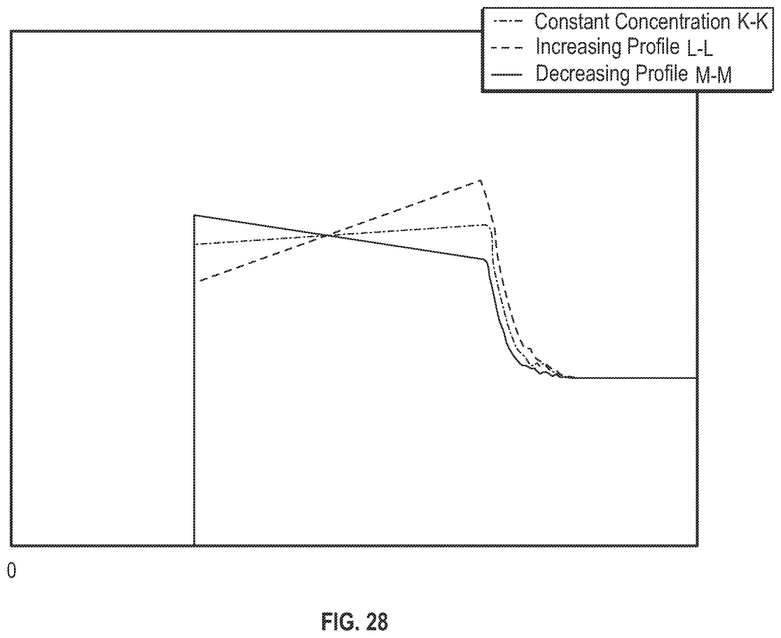

In various trench MOSFET implementations, the concentration of the n-type dopant in the n-type doped pillars can be varied along the length/distance/direction of the pillar into the material of the first and second epitaxial layers. Referring to FIG. 25, an implementation of a trench MOSFET implementation 86 is illustrated with an n-doped pillar 88 with a substantially constant concentration of n-type dopant showing sectional line K-K. Referring to FIG. 26, an implementation of a trench MOSFET implementation 90 is illustrated with a n-doped pillar 92 that has an increasing profile, or a concentration gradient of n-type dopant that increases as the pillar extends into the material of the first and second epitaxial layers (substrate). FIG. 27 illustrates an implementation of a trench MOSFET 94 that has an n-doped pillar 96 that has a decreasing profile, or a concentration gradient of n-type dopant that decreases as the pillar extends in to the material of the first and second epitaxial layers (substrate). FIG. 28 illustrates the one dimensional (into the paper) logarithm of the concentration gradient of n-type dopant in each n-type doped pillar 88, 92, 96, showing constant, increasing, and decreasing profiles, respectively, into the depth of the material. The ability to form a concentration gradient of n-type dopant in the n-type doped pillars into the material may allow for tuning the trench MOSFET to operate more stably in reverse blocking mode and/or for turning of the capacitance curve to improve switching performance.

The various trench MOSFET device implementations illustrated in this document may be manufactured using various methods of forming trench MOSFET devices. One of the main challenges of implanting dopants into silicon carbide is because implantation tends to be shallow compared to single crystal silicon requiring high implantation energies (about 1.1 mega-electron volts [MeV] needed to implant to about 1 micron depth). In addition, dopants do not substantially diffuse in silicon carbide, so the use of drive-in and other techniques to move dopants further in is not useful. Thus it is quite difficult to implant p-type dopants more than 2 microns into silicon carbide. In order to do so, where the p-type dopant is aluminum, over 2-3 MeV energies would be needed to form an implant over 2 microns into a silicon carbide substrate. When doing this, a thick hard mask oxide (over 4 microns thick) is also needed to protect the undoped regions and the thickness of the oxide acts to limit the pitch of the transistor cells that can be manufactured and doped successfully given the aspect ratio of the features that need to be doped. While angled channeling implants at 4 degrees from the face of the substrate can be used, as the c-plane of silicon carbide in most substrates is angled at 4 degrees from the face of the silicon carbide substrate (and similarly in many epitaxial silicon carbide layers grown), the ability to use angled implantation to increase the depth of the implantation is generally not significant enough to avoid having to use high implantation energies.

The various method implementations disclosed in this document, instead of employing very high implant energies, use an intermediate epitaxial growth/regrowth process followed by another round of implantation to construct implants into silicon carbide that can exceed 2 microns in depth for both n-type and p-type dopants. The use of multiple regrowth layers also permits the construction of continuously implanted regions of any desired depth into silicon carbide.

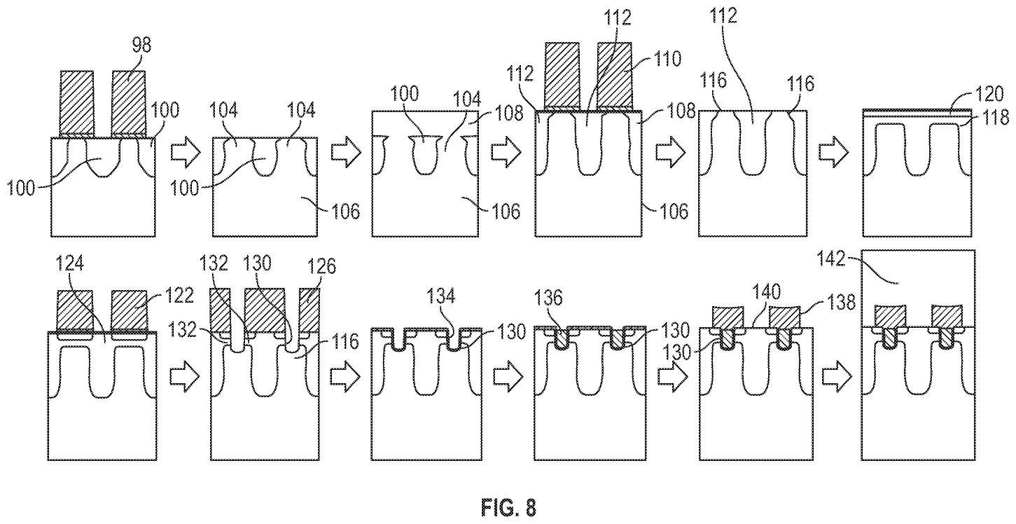

Referring to FIG. 8, a flow chart of a first implementation of a method of forming a trench MOSFET is illustrated. As illustrated, following formation of an implant blocking pattern 98, a first p-type implant is carried out to form p-type doped regions 100. The blocking pattern 98 may be formed of a photoresist material using lithographic processing steps and a photoresist or may be formed of a hard mask material (oxide, nitride) formed of one or more layers designed to protect the masked areas from implantation (using corresponding additional photolithographic steps to pattern and etch the hard mask). In a particular implementation, the p-type dopant is aluminum.

Following the completion of the first p-type implant, the blocking pattern 98 is removed and a first n-type implant is then carried out to form n-type doped regions 104 in the material of the substrate (which in this case is the first epitaxial layer 106). In a particular implementation, the n-type dopant is nitrogen.

Following the first p-type implant and first n-type implant, and a second silicon carbide epitaxial growth process is carried out to form second epitaxial layer 108 above the first epitaxial layer 106 and over the p-type doped regions 100 and n-type doped regions 104.

In a particular implementation, the second epitaxial layer may be grown to about 1 micron in thickness at a n-type dopant concentration of 9.5×10¹⁵/cm³ where the n-type dopant is nitrogen. As this growth of the second epitaxial layer can repair implant damage in the first epitaxial layer caused by the implantation processes, it may be referred to as a regrowth process and a regrowth layer.

Following growth of the second epitaxial layer 108, a second blocking layer 110 is formed over the n-type doped regions 104 and a second p-type implant is carried out into the p-type doped regions 100 forming p-type doped pillars 112 into the second epitaxial layer 108 and the first epitaxial layer 106. In a particular implementation, the second p-type implant is done where aluminum is the dopant. As illustrated in FIG. 8, following the second p-type implant, the second blocking layer 110 is removed and a second n-type implant into the n-type doped regions is carried out, forming n-type doped pillars 116. In a particular implementation, the second n-type implant may use nitrogen as the dopant. The effect of carrying out the n-type implants is that the n-type doped pillars 116 have a higher concentration of n-type dopant than the material of the first epitaxial layer 106, the second epitaxial layer 108, and/or the substrate itself in various implementations. Multiple epitaxial regrowth steps followed by additional n-type and p-type doping steps to form the variously doped pillars may be employed in various method implementations.

Following the second n-type implant, a p-type implant 118 is carried out across the surface of the substrate to establish the depth of what will become a trench channel. An n⁺ implant is then carried out, forming n⁺ region 120 establishing the upper boundary of the trench channel structure, followed the formation of a third blocking layer 122. A p⁺ implant is then carried out to form p⁺ region 124 followed by removal of the third blocking layer 122.

Trench patterning layer 126 is then formed using any of the patterning materials using any of the patterning techniques disclosed in this document. Trenches 130 are then formed using an etching process (wet, dry, etc.) down to the material of the n-type doped pillars 116, forming the trench channel 132 on each side of the trench 130. Following removal of the trench patterning layer 126, gate oxide 134 is formed over the surface of the substrate down into the trenches 130. In a particular implementation, the gate oxide is silicon dioxide. A majority of each trench is then filled with a gate material 136, which in a particular implementation is polysilicon. The polysilicon may be grown using a chemical vapor deposition process followed by an etch back or chemical mechanical planarization (CMP) polishing/grinding process to remove excess polysilicon from the surface of the substrate in various implementations. Additional oxide is then grown over and into the trench 130 and an etching process used to form contact areas 140 between the oxide 138. Following the oxide formation, metal 142 is then deposited over the oxide and formed into a desired pattern (using additional photolithography and etching steps as needed) to allow the gates of the various trench MOSFETS to be electrically connected and routed as desired.

The foregoing method can be modified using more or fewer sequential n-type dopant implants to increase or decrease the amount of n-type dopant in the n-type doped pillars 116. The method can also be modified by changing the dopant dose received during one or more of the consecutively applied n-type dopant implants to create n-type doped pillars with different constant n-type dopant concentrations or increasing or decreasing dopant profiles. The same principles can be used to control the p-type doping of the p-type doped pillars to allow the concentration of the pillars to be varied constantly or through creating increasing or decreasing p-type dopant concentrations along the length of the p-type doped pillars 112.

The foregoing method implementation can be modified in various implementations. For example, the initial processes of forming p-type doped regions 144 and n-type doped regions 146 followed by the growth of the second epitaxial layer 148 may be the same as in the method implementation of FIG. 8 except a first spacing between the patterned elements of the first blocking layer is wider than a spacing between the patterned elements of the second blocking layer. The narrower spacing results in the formation of a wider second region in the p-type doped pillars into the material of the substrate than the width of first region. As illustrated, the remaining processing steps in the method are the same as those previously described in the method implementation of FIG. 8 resulting in the formation of the trench MOSFET devices with a wider lower portion to the p-type doped pillars. Those of ordinary skill in the art will readily be able to apply the principles disclosed herein to form various methods of forming trench MOSFET devices like those disclosed in this document.

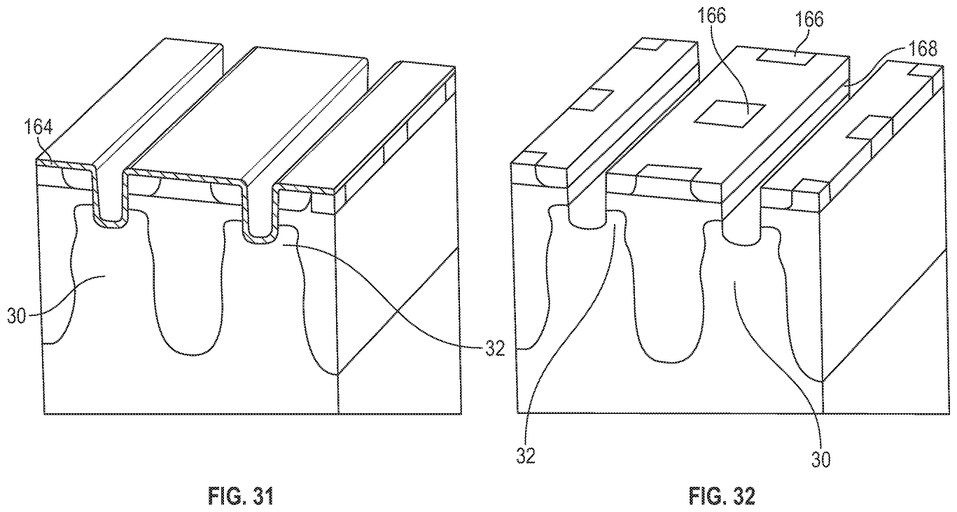

FIGS. 29-32 illustrate three dimensional versions of trench MOSFET devices at two intermediate steps of manufacture. FIGS. 29 and 31 illustrate where the gate oxide 162 has been applied. FIGS. 30 and 32 illustrate where the oxide is absent, showing the location of the pattern of p⁺ regions 166 adjacent to the trenches 168. The particular device illustrated in FIGS. 29-32 is a stripe cell. However, the principles in this document can be readily applied by those of ordinary skill to other trench MOSFET device types including, by non-limiting example, rectangular designs, hexagonal designs, and any other MOSFET device arrangement/configuration. Also, while the structure of the trench MOSFET devices disclosed in this document has focused on those where the trenches are formed into the n-type doped pillars and the epitaxial layers are n-type doped, the same principles could be applied to devices where the trenches are formed into the p-type doped pillars and the epitaxial layers are p-type doped.

In places where the description above refers to particular implementations of trench channel devices and implementing components, sub-components, methods and sub-methods, it should be readily apparent that a number of modifications may be made without departing from the spirit thereof and that these implementations, implementing components, sub-components, methods and sub-methods may be applied to other trench channel devices.

What is claimed is:

1. A semiconductor device comprising:
a trench comprising a gate and a gate oxide formed therein, the trench extending into a doped pillar of a first conductivity type formed in a substrate material;
a trench channel adjacent to the trench; and
two doped pillars of a second conductivity type extending on each side of the first conductivity type doped pillar where a ratio of a depth of each of the two second conductivity type doped pillars to a depth of the trench into the substrate material is at least 1.6 to 1.

2. The device of claim 1, wherein the first conductivity type doped pillar is n-type doped with nitrogen and the second conductivity type doped pillars are p-type doped with aluminum.

3. The device of claim 2, wherein the depth of each of the two p-type doped pillars extends between 0.5 to over 2 microns into the substrate material beyond the depth of the trench into the substrate material.

4. The device of claim 1, wherein the substrate material is silicon carbide.

5. The device of claim 1, further comprising p⁺ and n⁺ doped regions on either side of the trench adjacent to the trench channel.

6. The device of claim 1, wherein the device is comprised in two or more epitaxial layers of silicon carbide.

7. A semiconductor device comprising:
a trench comprising a gate and a gate oxide formed therein, the trench extending into an n-type doped pillar formed in a substrate material;
a trench channel adjacent to the trench; and
two p-type doped pillars extending on each side of the n-type doped pillar into the substrate material, the two p-type doped pillars each comprising a first region adjacent to the trench channel and a second region where the second region is wider than the first region.

8. The device of claim 7, wherein the n-type doped pillar is doped with nitrogen and the two p-type doped pillars are doped with aluminum.

9. The device of claim 7, wherein the substrate material is silicon carbide.

10. The device of claim 7, further comprising p⁺ and n⁺ doped regions on either side of the trench adjacent to the trench channel.

11. The device of claim 7, wherein the device is comprised in two epitaxial layers of silicon carbide.

12. A semiconductor device comprising:
a trench comprising a gate and a gate oxide formed therein, the trench extending into an n-type doped pillar formed in a substrate material;
a trench channel adjacent to the trench; and
two p-type doped pillars extending on each side of the n-type doped pillar;
wherein the n-type doped pillar has a higher concentration of n-type dopant than a concentration of n-type dopant in the substrate material.

13. The device of claim 12, wherein the n-type doped pillar is doped with nitrogen and the two p-type doped pillars are doped with aluminum.

14. The device of claim 12, wherein the substrate material is silicon carbide.

15. The device of claim 12, wherein an n-type dopant concentration of the n-type doped pillar is configured to adjust a capacitance curve of the device.

16. The device of claim 12, further comprising p⁺ and n⁺ doped regions on either side of the trench adjacent to the trench channel.

17. The device of claim 12, wherein the device is comprised in two epitaxial layers of silicon carbide.

18. A semiconductor device comprising:
a trench comprising a gate and a gate oxide formed therein, the trench extending into an n-type doped pillar formed in a substrate material;
a trench channel adjacent to the trench; and
two p-type doped pillars extending on each side of the n-type doped pillar;
wherein the n-type doped pillar has a varying concentration of n-type dopant from a first portion adjacent to the gate oxide to a second portion adjacent to the substrate material.

19. The device of claim 18, wherein the n-type doped pillar is doped with nitrogen and the two p-type doped pillars are doped with aluminum.

20. The device of claim 18, wherein the substrate material is silicon carbide.

21. The device of claim 18, wherein an n-type dopant concentration gradient increases from the first portion to the second portion.

22. The device of claim 18, wherein an n-type dopant concentration of the n-type doped decreases from the first portion to the second portion.

23. The device of claim 18, further comprising p⁺ and n⁺ doped regions on either side of the trench adjacent to the trench channel.

24. The device of claim 18, wherein the device is comprised in two epitaxial layers of silicon carbide.

25. A method of forming a semiconductor device, the method comprising:
implanting a silicon carbide substrate with a p-type dopant to form a plurality of p-type doped regions in the silicon carbide substrate;
implanting the silicon carbide with an n-type dopant to form a plurality of n-type doped regions in the silicon carbide substrate;
growing an epitaxial silicon carbide layer on the silicon carbide substrate after implanting the silicon carbide substrate with the n-type dopant;
after growing the epitaxial silicon carbide layer, implanting with a p-type dopant to form a plurality of p-type doped pillars in the silicon carbide substrate;
implanting with an n-type dopant to form a plurality of n-type doped pillars in the silicon carbide substrate;
forming a plurality of trenches into the plurality of n-type doped pillars;
depositing a gate oxide into the plurality of trenches;
depositing a polysilicon oxide material into the plurality of trenches; and
forming a plurality of contacts coupled with the polysilicon oxide material and the gate oxide.

26. The method of claim 25, wherein implanting the silicon carbide substrate with the p-type dopant to form the plurality of p-type doped regions in the silicon carbide substrate further comprises:
first forming a hard mask pattern having a plurality of first openings at a first opening width before implanting with the p-type dopant to form the plurality of p-type doped regions; and
after growing the epitaxial silicon carbide layer, first forming a hard mask pattern having a plurality of second openings at a second opening width before implanting with the p-type dopant to form the plurality of p-type doped pillars;
wherein the second opening width is smaller than the first opening width.

27. The method of claim 25, wherein implanting the silicon carbide substrate with the n-type dopant to form the plurality of n-type doped regions in the silicon carbide substrate further comprises implanting a first predetermined number of times with the n-type dopant; and
wherein implanting with the n-type dopant to form the plurality of n-type doped pillars in the silicon carbide substrate further comprises implanting a second predetermined number of times with the n-type dopant;
wherein the first predetermined number of times is more than the second predetermined number of times.

28. The method of claim 25, wherein implanting the silicon carbide substrate with the n-type dopant to form the plurality of n-type doped regions in the silicon carbide substrate further comprises implanting a first predetermined number of times with the n-type dopant; and
wherein implanting with the n-type dopant to form the plurality of n-type doped pillars in the silicon carbide substrate further comprises implanting a second predetermined number of times with the n-type dopant;
wherein the first predetermined number of times is less than the second predetermined number of times.

29. The method of claim 25, wherein implanting the silicon carbide substrate with the n-type dopant to form the plurality of n-type doped regions in the silicon carbide substrate further comprises implanting a first predetermined number of times with the n-type dopant; and
wherein implanting with the n-type dopant to form the plurality of n-type doped pillars in the silicon carbide substrate further comprises implanting a second predetermined number of times with the n-type dopant;
wherein the first predetermined number of times is the same as the second predetermined number of times.

30. The method of claim 25, further comprising varying a capacitance curve using an n-type dopant concentration of the n-type doped pillars.

31. A semiconductor device comprising:
a trench comprising a gate and a gate oxide formed therein, the trench extending into a doped pillar of a first conductivity type formed in a substrate material;
a trench channel adjacent to the trench; and
two doped pillars of a second conductivity type extending on each side of the first conductivity type doped pillar where a depth of each of the two second conductivity type doped pillars extends between 0.5 to 2 microns into the substrate material beyond a depth of the trench into the substrate material.

32. The device of claim 31, wherein the first conductivity type doped pillar is n-type doped with nitrogen and the two second conductivity type doped pillars are p-type doped with aluminum.

33. The device of claim 31, wherein the substrate material is silicon carbide.

34. The device of claim 31, further comprising p⁺ and n⁺ doped regions on either side of the trench adjacent to the trench channel.

35. The device of claim 31, wherein the device is comprised in two or more epitaxial layers of silicon carbide.
